(19) United States
(12) Patent Application Publication
(10) Pub. No.: US 2004/0264283 A1
(43) Pub. Date: Dec. 30, 2004

(54) Method for playing multimedia files in a terminal

(76) Inventor: Hartwig Koch, Hildesheim (DE)

Correspondence Address: KENYON & KENYON, ONE BROADWAY, NEW YORK, NY, 10004, US

(21) Appl. No.: 10/487,686

(22) PCT Filed: Aug. 16, 2002
(86) PCT No.: PCT/DE02/03002

(30) Foreign Application Priority Data
Aug. 24, 2001 (DE) 10141607.5

(51) Int. Cl. G11C 8/02

(52) U.S. Cl. 365/232

(57) ABSTRACT

A method for playing multimedia files in a terminal, in which audio files are played depending on the situation when managing the stored multimedia files, thus giving the user a blind management capability for the multimedia files. The multimedia and audio files are preferably received via radio signals, in particular via digital broadcasting signals.

### BACKGROUND INFORMATION

The present invention is directed to a method for playing multimedia files in a terminal according to the definition of the species of the independent claim.

A device for providing information to the driver of a motor vehicle is already known from Unexamined Patent Application DE 38 42 417 A1, which describes a digital voice memory for providing information to the driver of a motor vehicle to which equipment such as a car radio, mobile telephone, hands-free equipment, CD player, positioning and navigation system and/or an alarm system are connectable. The digital voice memory is divided into multiple memory areas in which information from the connected equipment can be stored. Part of the memory is designed to be variable for optimum utilization and is expandable as a function of the information to be stored. Output is acoustic via the car radio loudspeakers or visual on a central monitor. Two special data input devices provide easy and straightforward control of the device in connection with the monitor.

### ADVANTAGES OF THE INVENTION

The method according to the present invention for playing multimedia files in a terminal, having the features of the independent patent claim, has the advantage over the related art that, when managing multimedia files, audio files are played depending on the situation, thus enabling the user to blindly navigate within the multimedia files. This is especially useful for users in a motor vehicle so that they do not have to concentrate visually on a terminal. User comfort is thereby enhanced, users are independent of a language used, and a display is not absolutely necessary.

The features and embodiments described in the dependent claims make it possible to advantageously improve the method for playing multimedia files in a terminal.

A further advantage is that the multimedia data and/or the audio data may be received by radio signals and then stored locally in the terminal. The audio data for managing the multimedia files is thus delivered automatically to the user by a radio broadcaster or a radio network operator. This enables the radio broadcaster or the producer of the audio data to add advertisements thereto. As a result, it is no longer necessary for the user to create or purchase these audio files himself.

It is also advantageous for the multimedia data to be stored in classified form after it is received. This means that an additional item of information on the multimedia file is used to detect the class to which this multimedia file belongs. Classes of this type are, for example, sports, news, weather or stock market. In addition, a more detailed classification is also achievable through subclasses, for example, international and local news or different kinds of sports such as soccer or track and field. The detailed classification is then carried out and detected by the terminal processor automatically.

It is also advantageous to assign a priority to these audio files and/or multimedia files and to store or delete the files according to this priority. When memory capacity is in short supply, low-priority audio files and/or multimedia files are deleted earlier, thereby maintaining terminal operation.

It is also advantageous for at least a portion of the audio files to be created by a user. This may be done, for example, in text form through manual input, by entering text that is subsequently converted to speech by a speech synthesizer, or by using a microphone and having the user record the text himself. He must also specify the situation in which this audio file is to be played. A simple menu guidance system makes it much easier for the user to perform such input and thus create an audio file of this type.

It is particularly advantageous to use digital broadcasting signals such as DAB (Digital Audio Broadcasting), DRM (Digital Radio Mondiale) or DVB (Digital Video Broadcasting) as the radio signals. These digital broadcasting signals make it extremely easy, in particular, to transmit multimedia files, since the frame structure used enables nearly any multimedia object to be transmitted.

In addition, it is advantageous to use a terminal for carrying out the method according to the present invention which includes a memory for storing the multimedia files and the audio files, an input device for managing the multimedia files, a loudspeaker for playing the multimedia files and the audio files, and a processor for decoding the multimedia files and the audio files, the audio files being played depending on the situation when managing the multimedia files. The terminal may have a radio station for receiving the multimedia files and the audio files, or it may be designed as a digital radio receiver.

### DRAWING

Exemplary embodiments of the present invention are illustrated in the drawing and explained in greater detail in the following description.

FIG. 1 shows a block diagram of the terminal according to the present invention;

FIG. 2 shows a first flow chart of the method according to the present invention; and

FIG. 3 shows a second flow chart of the method according to the present invention.

### DESCRIPTION OF THE EXEMPLARY EMBODIMENTS

DAB (Digital Audio Broadcasting) is a broadcasting method that provides the listener with fully compiled radio programs. Personalized options are available as add-ons. In this case, multimedia objects, preferably audio files, are broadcast, stored locally in the radio receiver and played offline according to user preferences. It is possible to navigate within these multimedia objects, for example, by remote control, as is already known from navigation and car radio equipment, or via control keys directly on the device. In certain situations, for example, when user input is given, only predefined audio files are to be played according to the present invention, which gives the user direct audio feedback on his actions.

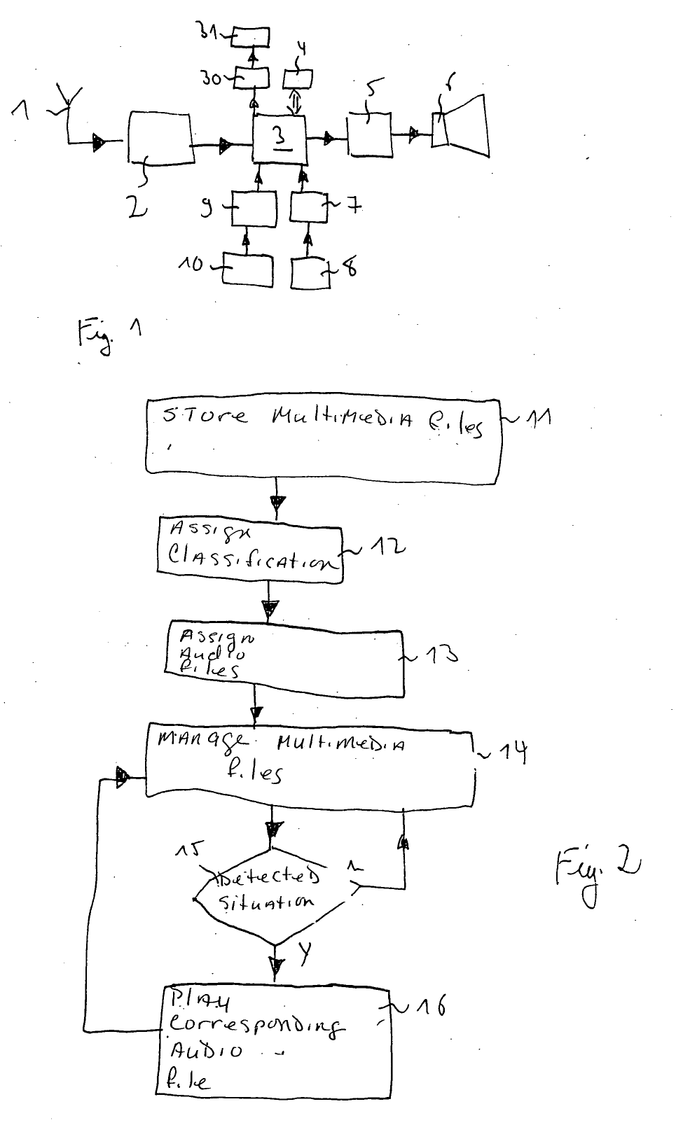

FIG. 1 shows a block diagram of a terminal according to the present invention that is designed in this case as a radio receiver. Alternatively, it is possible to design the terminal without a radio receiver, or a mobile communications device like those known from UMTS (Universal Mobile Telecommunications System) may be provided. In particular, mobile communications devices of this type are designed for mobile reception of multimedia objects. The method according to the present invention is also suitable, in particular, for such mobile communications devices.

An antenna 1 is connected to an input of a high-frequency receiver 2. An output of high-frequency receiver 2 is connected to a first data input of a processor 3, which is connected to a memory 4 via a data input/output. Processor 3 is connected via an output to an audio amplifier 5 that drives a loudspeaker 6. A signal processing system 7, which processes the input signals from an input device 8, is connected to a second data input of processor 3. A signal processing system 9, which processes the signals from a microphone 10, is connected to a third data input. Processor 3 is connected via a data output to a signal processing system 30 that controls a monitor 31. Monitor 31 may be designed as an LCD or plasma screen or using a different known display technology.

Alternatively, it is possible to provide a transceiver station instead of a high-frequency receiver 2, or to dispense with radio reception altogether and use only stationary data.

The multimedia files are received via antenna 1 and high-frequency receiver 2 in the form of broadcasting signals, amplified and converted to an intermediate frequency as well as digitized. Processor 3 detects the received multimedia files and stores them in memory 4 according to a classification system. Memory 4 may be a hard disk, a chip card or a different rewritable memory, such as a semiconductor memory. In this case, this local storage may be carried out in a directory structure that has folders for sports, news, weather and stock market on the main level. Additional subfolders break down the above-mentioned topics even further. Navigation within the classification system takes place, for example, using input device 8, which in this case is designed as arrow keys. Monitor 31 may provide the user with visual feedback on the present class, for example, news or local news. In this case, monitor 31 is designed as a one-line display. Other classification systems may be used to a nearly unlimited extent by making appropriate settings.

While navigating through the folders, the user then receives audio feedback associated with a certain situation. Situations of this type are, for example, selecting a folder such as “News.” The audio files correspondingly linked to this folder, which help the user perform management tasks, specify the folder (for example “News”) in which he is presently located, whether this folder contains any elements, no elements, new elements, as yet unheard elements, or how many elements are stored in this folder. Other options are conceivable here. Alternatively, this audio feedback may take place in addition to text output.

Organizing multimedia files into a directory structure may be accomplished using an index.mp3 object in the folder concerned. This object is played automatically when the folder is selected. Another option is to name the audio file according to the classification itself, for example, News local.mp3, and to execute it as needed. This need is detected by processor 3 and depends on a manual selection using input device 8. This index object may be coded in mp3 format or a different audio coding format, for example, MPEG 1, 2, 4 and layers 1 through 3, ACC or text-to-speech.

The device according to the present invention enables blind operation, since the audio files always identify for the user the folder in which he is presently located. This procedure may be expanded by having the audio files indicate which audio files or multimedia files are stored here, ultimately creating a list in the audio file concerned. This may be carried out automatically by processor 3.

This system may be enhanced dynamically and independently of the language used, since the content of the audio files is produced or broadcast solely by the broadcasters, or it is created by the user. The general audio impression may be improved by having a human speaker rather than an artificial voice record the text. If desired, text of this type may be provided with promotional messages, for example “news sponsored by Bosch.” The use of priorities for these audio files makes it possible, when memory volume is low, to discard low-priority audio files. If priorities are assigned to all files, including the multimedia files, it is also possible to delete multimedia files, if necessary.

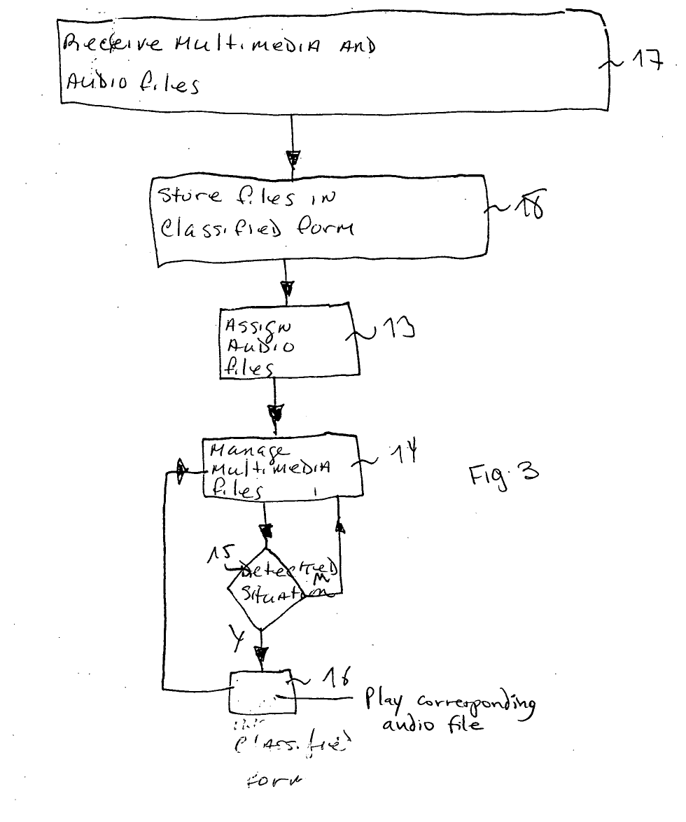

FIG. 2 shows a block diagram of the method according to the present invention for playing multimedia files in a terminal. In method step 11, multimedia files are stored in memory 4. These multimedia files are either received via radio signals or recorded by a user via a memory. They may also be created using microphones and video cameras. In method step 12, markers in the multimedia files are used to classify multimedia files and assign them to individual folders.

In method step 13, the individual folders are assigned audio files that are played depending on the situation when the folder is selected, enabling the user to operate the device blindly. In method step 14, the multimedia files are managed by a user. Processor 3 then detects situations in method step 15, such as the selection of a particular folder. If a corresponding audio file is present, this audio file is played in method step 16, giving the user audio feedback on his actions. This enables the user to operate the device blindly. If a predefined situation is not detected in method step 15, no audio file is played, and the method returns to step 14 to continue managing the multimedia files.

FIG. 3 shows a second block diagram of the method according to the present invention. In this case, multimedia files and audio files are explicitly received in method step 17, using digital broadcasting signals. In method step 18, these received files are classified and stored on the basis of their markers. In method step 13, the audio files are assigned to the individual classes, as described above. In method step 14, the user manages the multimedia files. In method step 15, the method checks whether a situation is detected. If so, the appropriate audio file is played in method step 16, then the method returns to the management of the multimedia files. If a situation of this type is not detected during management of the multimedia files in method step 15, the method returns directly to method step 14 and continues managing the multimedia files.

1-10. (Canceled).

11. A method for playing multimedia files in a terminal, the multimedia files being used for at least one of entertainment and information purposes, the method comprising:
using audio files to manage the multimedia files; and
playing the audio files in predefined situations when managing the multimedia files.

12. The method according to claim 11, further comprising receiving at least one of (a) the multimedia files and (b) the audio files via radio signals and then storing the at least one of (a) and (b) locally.

13. The method according to claim 11, further comprising storing the multimedia files in classified form.

14. The method according to claim 12, further comprising assigning the audio files a priority and at least one of storing and deleting the audio files according to the priority.

15. The method according to claim 11, further comprising creating, by a user, at least a portion of the audio files.

16. The method according to claim 12, wherein the audio files, in part, contain advertisements.

17. The method according to claim 12, wherein the radio signals include digital broadcasting signals.

18. A terminal comprising:
a memory for storing multimedia and audio files;
an input device for managing the multimedia files;
a loudspeaker for playing the multimedia and audio files; and
a processor for decoding the multimedia and audio files and for playing the audio files depending on a situation when managing the multimedia files.

19. The terminal according to claim 18, further comprising a radio station.

20. The terminal according to claim 18, wherein the terminal is designed as a digital radio receiver.
